(19) United States
(12) Patent Application Publication
(10) Pub. No.: US 2025/0204027 A1
(43) Pub. Date: Jun. 19, 2025

(54) SEMICONDUCTOR DEVICE

(71) Applicant: FUJI ELECTRIC CO., LTD., Kawasaki-shi, Kanagawa (JP)

(72) Inventor: Takahide TANAKA, Matsumoto-city (JP)

(73) Assignee: FUJI ELECTRIC CO., LTD., Kawasaki-shi, Kanagawa (JP)

(21) Appl. No.: 18/931,693

(22) Filed: Oct. 30, 2024

(30) Foreign Application Priority Data
Dec. 15, 2023 (JP) 2023-211609

(51) Int. Cl. H01L 27/06; H01L 29/78; H02M 1/088; H03K 19/0185

(52) U.S. Cl. CPC H10D 84/811; H10D 1/47; H10D 30/65; H02M 1/088; H03K 19/018507

(57) ABSTRACT

A semiconductor device includes: a base body of a first conductivity-type; a first well region of a second conductivity-type provided in the base body with a high-side circuit; a second well region of the first conductivity-type provided in the first well region; a first voltage blocking region of the second conductivity-type provided around the first well region; a contact region of the second conductivity-type provided in the first well region or the first voltage blocking region; a slit region of the first conductivity-type provided between the second well region and the contact region in the first well region and connected to the second well region via a resistor; a second voltage blocking region of the first conductivity-type provided on an outer circumferential side of the first voltage blocking region; and a level shifter provided to execute a signal transmission between a low-side circuit and the high-side circuit.

### CROSS-REFERENCE TO RELATED APPLICATION

This application claims benefit of priority under 35 USC 119 based on Japanese Patent Application No. 2023-211609 filed on Dec. 15, 2023, the entire contents of which are incorporated by reference herein.

### BACKGROUND OF THE INVENTION

### 1. Field of the Invention

The present invention relates to semiconductor devices.

### 2. Description of the Related Art

JP6008054B2 discloses a high-voltage integrated circuit (HVIC) having a configuration in which a p-type region with a reference potential (a VS potential) in a high-side circuit is provided separately from an n-type region with a power-supply potential (a VB potential) in the high-side circuit so as to avoid a formation of a parasitic pnp bipolar transistor.

JP6447139B2 discloses an HVIC in which some of the sides are provided with a p-type slit, while at least one side is not provided with the p-type slit, so as to absorb a hole current on the side not provided with the p-type slit to hardly lead the current to flow into a high-side circuit in order to enhance tolerance to noise that leads to a relation of “VB potential<ground potential (GND potential)”.

JP5099282B1 discloses a HVIC in which a contact region with a VB potential is provided with not only an n⁺-type region but also a p⁺-type region so as to absorb a hole current in the n⁺-type region and the p⁺-type region to hardly lead the current to flow into a high-side circuit.

Conventional HVICs are operated in a state of keeping a potential relation of “VB potential>VS potential>GND potential”.

However, a parasitic operation would be induced if this potential relation is broken because of noise or the like, which would cause wrong operations or damage. The HVICs as disclosed in JP 6008054B, JP 6447139B, and JP 5099282B constantly need to deal with the problem of noise through various approaches, since these HVICs would not be applied to some cases depending on target chip sizes or design ideas or sometimes do not have sufficient tolerance to noise by themselves.

### SUMMARY OF THE INVENTION

In view of the foregoing problems, the present invention provides a semiconductor device having a configuration capable of improving tolerance to wrong operations or damage caused by noise or the like.

An aspect of the present invention inheres in a semiconductor device including: a base body of a first conductivity-type; a first well region of a second conductivity-type provided in the base body so as to be provided with a high-side circuit; a second well region of the first conductivity-type provided at an upper part of the first well region; a first voltage blocking region of the second conductivity-type having a lower impurity concentration than the first well region and provided around the first well region; a contact region of the second conductivity-type having a higher impurity concentration than the first well region and provided at an upper part of the first well region or the first voltage blocking region; a slit region of the first conductivity-type provided between the second well region and the contact region at the upper part of the first well region and connected to the second well region via a resistor; a second voltage blocking region of the first conductivity-type provided on an outer circumferential side of the first voltage blocking region so as to be in contact with each other; and a level shifter provided to execute a signal transmission between a low-side circuit provided on an outer circumferential side of the second voltage blocking region and the high-side circuit.

### BRIEF DESCRIPTION OF THE DRAWINGS

FIG. 1 is a circuit diagram illustrating a semiconductor device according to a first embodiment;

FIG. 2 is a plan view illustrating the semiconductor device according to the first embodiment;

FIG. 3 is a cross-sectional view illustrating the semiconductor device according to the first embodiment taken along line A-A′ in FIG. 2;

FIG. 4 is a cross-sectional view illustrating a region including a polysilicon resistor in the semiconductor device according to the first embodiment;

FIG. 5 is a cross-sectional view illustrating the semiconductor device according to the first embodiment taken along line B-B′ in FIG. 2;

FIG. 6 is a plan view illustrating a semiconductor device of a comparative example;

FIG. 7 is a cross-sectional view illustrating the semiconductor device of the comparative example taken along line A-A′ in FIG. 6 when falling into a potential relation of “VS potential>VB potential>>GND potential”;

FIG. 8 is a cross-sectional view illustrating the semiconductor device according to the first embodiment taken along line A-A′ in FIG. 2 when falling into a potential relation of “VS potential>VB potential»>GND potential”;

FIG. 9 is a cross-sectional view illustrating the semiconductor device of the comparative example taken along line A-A′ in FIG. 6 when falling into a potential relation of “VB potential<VS potential”;

FIG. 10 is a cross-sectional view illustrating the semiconductor device according to the first embodiment taken along line A-A′ in FIG. 2 when falling into a potential relation of “VB potential<VS potential”;

FIG. 11 is a cross-sectional view illustrating the semiconductor device of the comparative example taken along line B-B′ in FIG. 6 when falling into a potential relation of “VB potential<GND potential”;

FIG. 12 is a cross-sectional view illustrating the semiconductor device according to the first embodiment taken along line B-B′ in FIG. 2 when falling into a potential relation of “VB potential<GND potential”;

FIG. 13 is a cross-sectional view illustrating a semiconductor device according to a second embodiment, corresponding to the cross section taken along line A-A′ in FIG. 2;

FIG. 14 is a cross-sectional view illustrating the semiconductor device according to the second embodiment, corresponding to the cross section taken along line B-B′ in FIG. 2;

FIG. 15 is a plan view illustrating a semiconductor device according to a third embodiment;

FIG. 16 is a cross-sectional view illustrating a semiconductor device according to a fourth embodiment, corresponding to the cross section taken along line A-A′ in FIG. 2;

FIG. 17 is a cross-sectional view illustrating the semiconductor device according to the fourth embodiment, corresponding to the cross section taken along line B-B′ in FIG. 2; and

FIG. 18 is a plan view illustrating a semiconductor device according to a fifth embodiment.

### DETAILED DESCRIPTION

With reference to the drawings, first to fifth embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to fifth embodiments described below merely illustrate schematically devices and methods for specifying and giving shapes to the technical idea of the present invention, and the span of the technical idea is not limited to materials, shapes, structures, and relative positions of elements described herein.

In the specification, a “carrier supply region” means a semiconductor region which supplies majority carriers as a main current. The carrier supply region is assigned to a semiconductor region which will be a source region in a field-effect transistor (FET) or a static induction transistor (SIT), an emitter region in an insulated-gate bipolar transistor (IGBT), and an anode region in a diode, a static induction (SI) thyristor or a gate turn-off (GTO) thyristor. A “carrier reception region” means a semiconductor region which receive the majority carriers as the main current. The carrier reception region is assigned to a semiconductor region which will be the drain region in the FET or the SIT, the collector region in the IGBT, and the cathode region in the diode, SI thyristor or GTO thyristor.

In the specification, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is a p-type and a second conductivity-type is an n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### First Embodiment

### <Circuit of Semiconductor Device>

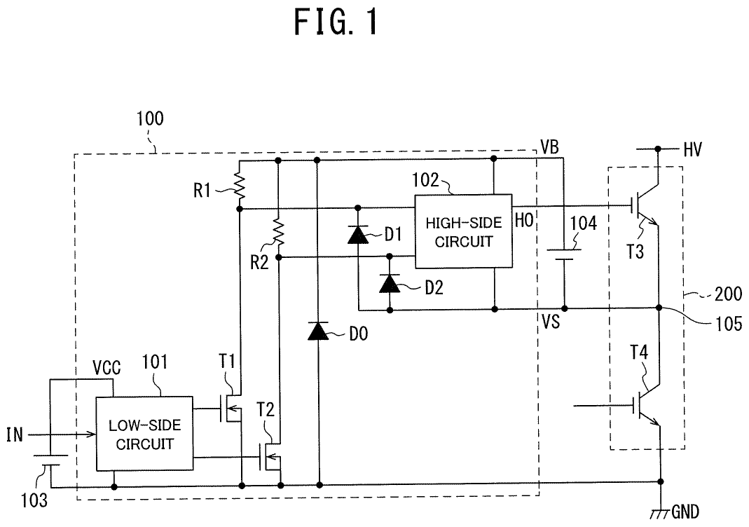

A semiconductor device according to a first embodiment is illustrated below with a high-voltage integrated circuit (HVIC) 100, as illustrated in FIG. 1. The HVIC 100 drives a power conversion part 200 as a target for one phase of a bridge circuit for power conversion, for example. The power conversion part 200 includes a high-potential-side switching element T3 and a low-potential-side switching element T4 connected in series so as to implement a half-bridge circuit. While FIG. 1 illustrates the case in which the high-potential-side switching element T3 and the low-potential-side switching element T4 are each an IGBT, the respective elements may be any other power switching element such as a metal-oxide-semiconductor field-effect transistor (MOSFET).

An HV potential on a high-potential side is connected to a collector of the high-potential-side switching element T3. A ground potential (a GND potential) on a low-potential side is connected to an emitter of the low-potential-side switching element T4. A VS potential on a negative-electrode side of a power supply (a high-potential-side power supply) 104 on the high-potential side is connected to a connection point 105 (an intermediate point of the half-bridge circuit) between an emitter of the high-potential-side switching element T3 and a collector of the low-potential-side switching element T4. A load (not illustrated) such as a motor is further connected to the connection point 105.

The HVIC 100 applies a drive signal, to a gate of the high-potential-side switching element T3, for turning on/off to drive the gate of the high-potential-side switching element T3 in accordance with an input signal IN from an external microcomputer, for example. The HVIC 100 includes a low-potential-side circuit (a low-side circuit) 101 and a high-potential-side circuit (a high-side circuit) 102. A VCC potential on the positive-electrode side of a power supply (a low-potential-side power supply) 103 on the low-potential side and a GND potential on the negative-electrode side of the low-potential-side power supply 103 are connected to the low-side circuit 101. Further, gates of level-shift elements (level shifters) T1 and T2 are connected to the low-side circuit 101.

The low-side circuit 101 operates with the GND potential used as a reference potential and with the VCC potential higher than the GND potential used as a power-supply potential. The low-side circuit 101 generates an ON/OFF signal based on the GND potential in accordance with the input signal IN from the external microcomputer or the like, and outputs the generated signal to the respective gates of the level shifters T1 and T2.

The respective level shifters T1 and T2 execute the signal transmission between the low-side circuit 101 and the high-side circuit 102. The respective level shifters T1 and T2 convert the ON/OFF signal based on the GND potential output from the low-side circuit 101 into an ON/OFF signal based on the VS potential, and outputs the converted ON/OFF signal to the high-side circuit 102. The respective level shifters T1 and T2 are each a high-voltage n-channel MOSFET, for example.

The GND potential is connected to a source of the level shifter T1. The high-side circuit 102 and one end of a level-shift resistor R1 are connected to a drain of the level shifter T1. A VB potential on the positive-electrode side of the high-potential-side power supply 104 is connected to the other end of the level-shift resistor R1. A cathode of a diode D1 is connected to the drain of the level shifter T1 and the one end of the level-shift resistor R1. The high-side circuit 102 and the VS potential on the negative-electrode side of the high-potential-side power supply 104 are connected to an anode of the diode D1. The diode D1 has a function of avoiding an excessive reduction in drain potential of the level shifter T1.

The GND potential is connected to a source of the level shifter T2. The high-side circuit 102 and one end of a level-shift resistor R2 are connected to a drain of the level shifter T2. The VB potential on the positive-electrode side of the high-potential-side power supply 104 is connected to the other end of the level-shift resistor R2. A cathode of a diode D2 is connected to the drain of the level shifter T2 and the one end of the level-shift resistor R2. The high-side circuit 102 and the VS potential on the negative-electrode side of the high-potential-side power supply 104 are connected to an anode of the diode D2. The diode D2 has a function of avoiding an excessive reduction in drain potential of the level shifter T2.

A cathode of a high-voltage diode DO, which is referred to as a high-voltage junction termination (HVJT) diode, is connected to the respective other ends of the level-shift resistors R1 and R2 and the VB potential on the positive-electrode side of the high-potential-side power supply 104. The GND potential is connected to an anode of the diode DO.

The high-side circuit 102 operates with the VS potential used as a reference potential and with the VB potential higher than the VS potential used as a power-supply potential. The high-side circuit 102 outputs a drive signal based on the VS potential to the gate of the high-potential-side switching element T3 in accordance with the ON/OFF signal from the respective level shifters T1 and T2 so as to drive the gate of the high-potential-side switching element T3. The high-side circuit 102 includes a CMOS circuit of an n-channel MOSFET and a p-channel MOSFET at the output stage, for example.

The VB potential is a maximum potential applied to the HVIC 100, and is kept higher than the VS potential by about 15 volts in a normal operation not influenced by noise. The VS potential repeats a rise and a drop between the HV potential on the high-potential side (about 400 to 600 volts, for example) and the GND potential on the low-potential side when the high-potential-side switching element T3 and the low-potential-side switching element T4 are complementarily turned on and off, and fluctuates between zero to several hundreds of volts. The VS potential can fall below zero.

### <Structure of Semiconductor Device>

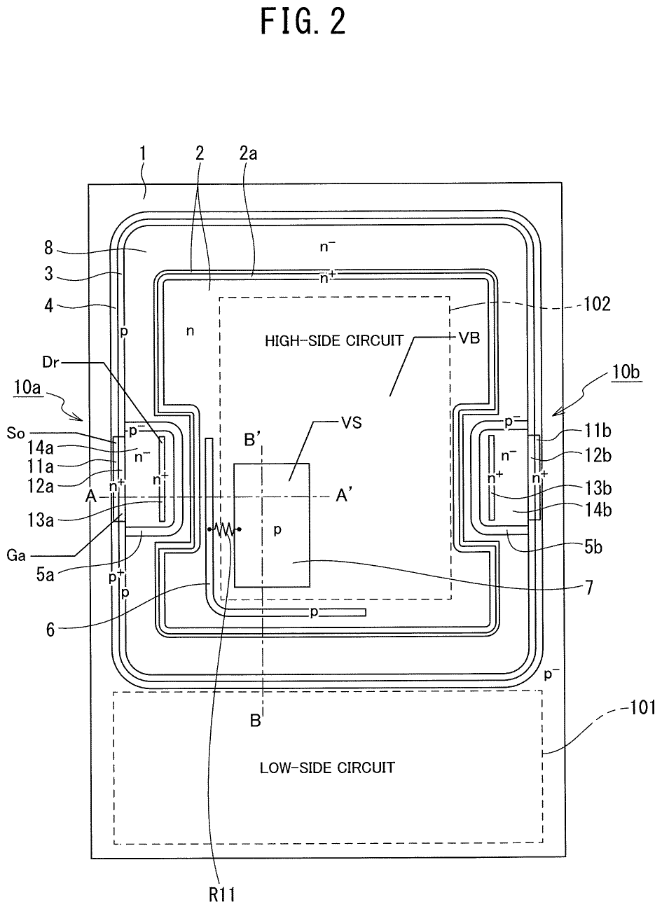

FIG. 2 is a planar layout of the semiconductor device according to the first embodiment corresponding to the HVIC 100 illustrated in FIG. 1. The HVIC 100 includes a base body (a semiconductor chip) 1 of a first conductivity-type (p⁻-type). The base body 1 is a silicon (Si) substrate, for example. The base body 1 may be implemented by a semiconductor substrate including silicon carbide (SiC), a gallium nitride (GaN), a gallium oxide (Ga₂O₃), gallium arsenide (GaAs), or diamond (C). Alternatively, the base body 1 may be implemented by a semiconductor substrate of p⁻-type and an epitaxial layer of p⁻-type grown on the semiconductor substrate. The bottom surface of the base body 1 may be fixed at a GND potential.

A well region (a first well region) 2 of a second conductivity-type (n-type) is provided at the upper part of the base body 1. The well region 2 has a substantially rectangular planar pattern. The well region 2 is provided with the high-side circuit (the high-side circuit region) 102. FIG. 2 omits the illustration of the elements included in the high-side circuit 102.

A pickup region (a contact region) 2a of the second conductivity-type (n⁺-type) having a higher impurity concentration than the well region 2 is provided at the upper part of the well region 2. FIG. 2 illustrates a case in which the contact region 2a is provided into a loop-shaped state along the outer circumference of the well region 2. The contact region 2a does not need to have the loop-like shape. For example, either a single contact region or a plurality of contact regions may be partly provided. Alternatively, the contact region 2a may be provided at an upper part of a voltage blocking region (a first voltage blocking region) 8 of n⁻-type in contact with the outer circumference of the well region 2, instead of the upper part of the well region 2. The VB potential that is the power-supply potential of the high-side circuit 102 is applied to the well region 2 through the contact region 2a.

A well region (a second well region) 7 of p-type is also provided at the upper part of the well region 2. The well region 7 has a substantially rectangular planar pattern. While FIG. 2 illustrates the case in which the well region 7 is provided on the lower left side of the well region 2 in the planar view in FIG. 2, the provided position of the well region 7 can be changed as appropriate when located inside the well region 2. The well region 7 may have any size. A plurality of well regions 7 may be provided at the upper part of the well region 2. The VS potential that is the reference potential of the high-side circuit 102 is applied to the well region 7.

A slit region 6 of p-type is provided between the contact region 2a and the well region 7 at the upper part of the well region 2. The slit region 6 has a substantially L-shaped planar pattern in the planar view in FIG. 2. The slit region 6 is partly provided between the contact region 2a and the respective two sides of the well region 7 located closer to the contact region 2a. The partial provision of the slit region 6 can reduce the area occupied by the slit region 6 as compared with a case in which the slit region 6 is provided into a loop-shaped state. The distance between the slit region 6 and the well region 7, the distance between the slit region 6 and the contact region 2a, and the width of the slit region 6 can be adjusted as appropriate.

Alternatively, the slit region 6 may be provided to partly have a substantially straight (stripe-shaped) planar pattern between the contact region 2a and the one side of the well region 7 located closest to the contact region 2a. Alternatively, the slit region 6 may be provided into a loop-shaped state so as to surround the well region 7 and the high-side circuit 102. When a plurality of well regions 7 are provided, either the single slit region 6 or a plurality of slit regions 6 of p-type may be provided between the plural well regions 7 and the contact region 2a.

The slit region 6 is connected to the well region 7 via a resistor R11. The VS potential that is the reference potential of the high-side circuit 102 is applied to the slit region 6 through the resistor R11. The value of the resistor R11 is in a range of about 10Ω or greater and 1 kΩ or smaller, for example, but is not limited to this range. The resistor R11 is a polysilicon resistor, for example. The resistor R11 may be a diffusion resistor instead.

The n-type voltage blocking region 8 having a lower impurity concentration than the well region 2 is provided to surround the well region 2 so as to be in contact with each other. The voltage blocking region 8 is provided into a substantially loop-shaped state to have an outline having a substantially rectangular planar pattern. A voltage blocking region (a second voltage blocking region) 3 of p-type is provided separately from the well region 2 by a predetermined distance. The voltage blocking region 3 is provided into a substantially loop-shaped state to have an outline having a substantially rectangular planar pattern. The GND potential is applied to the voltage blocking region 3. The voltage blocking region 3 is surrounded by the base body 1.

A p-n junction between the voltage blocking region 8 and the voltage blocking region 3 implements a high-voltage junction termination (HVJT) (3, 8). The HVJT (3, 8) corresponds to the high-voltage diode DO illustrated in FIG. 1. The HVJT (3, 8) is provided into a substantially loop-shaped state to have an outline having a substantially rectangular planar pattern. The HVJT (3, 8) electrically isolates the well region 2 on the inner circumferential side of the voltage blocking region 8 from the low-side circuit (the low-side circuit region) 101 provided in the base body 1 on the outer circumferential side of the voltage blocking region 8. The provision of the HVJT (3, 8) enables a normal operation of the semiconductor device regardless of whether the potential of the high-side circuit 102 is led to be higher than the potential of the low-side circuit 101 by several hundreds of volts.

A part of the HVJT (3, 8) implemented by the n-type voltage blocking region 8 and the p-type voltage blocking region 3 is integrally provided with level shifters 10a and 10b. The level shifters 10a and 10b are each a high-voltage n-channel MOSFET. The respective level shifters 10a and 10b correspond to the respective level shifters T1 and T2 illustrated in FIG. 1.

A method of forming the MOSFET used as the respective level shifters T1 and T2 illustrated in FIG. 1 is broadly divided into two methods, one of which is referred to as a wire-bonding method (a WB method), and the other one is referred to as a self-shielding method (an SS method). The WB method forms the MOSFET independently of the HVJT (3, 8) to connect a drain potential (a Dr potential) of the MOSFET to the high-side circuit 102 via bonding wires. The SS method forms the MOSFET so as to integrate the HVJT (3, 8) with each other. The semiconductor device according to the first embodiment is illustrated with the case in which the respective level shifters 10a and 10b are formed by the SS method.

The respective level shifters 10a and 10b are provided on the opposite sides of the rectangular shape from each other in the planar pattern of the HVIT (3, 8). The planar pattern of the well region 2 and the contact region 2a has internally recessed parts so as to partly surround the respective level shifters 10a and 10b. The positions of the respective level shifters 10a and 10b are not limited to the case as illustrated, and both of the level shifters 10a and 10b may be provided on the common side of the rectangular shape of the planar pattern of the HVJT (3, 8). The respective level shifters 10a and 10b are electrically isolated from the well region 2 by isolation regions 5a and 5b of p-type provided in the voltage blocking region 8. The isolation regions 5a and 5b each have a U-shaped planar pattern so as to surround the respective circumferences of the level shifters 10a and 10b.

The level shifter 10a is opposed to the well region 7 with the isolation region 5a, the contact region 2a, and the slit region 6 interposed. The level shifter 10a includes a carrier supply region (a source region) 11a of n⁺-type, a gate electrode 12a, and a carrier reception region (a drain region) 13a of n⁺-type. The source region 11a, the gate electrode 12a, and the drain region 13a each have a straight planar pattern extending parallel to each other. A part of the voltage blocking region 8 interposed between the source region 11a and the drain region 13a serves as a drift region 14a of the level shifter 10a. The GND potential is applied as a source potential (So potential) to the source region 11a. The drain potential (Dr potential) is applied to the drain region 13a.

The level shifter 10b has substantially the same configuration as the level shifter 10a, namely, includes a source region 11b of n⁺-type, a gate electrode 12b, and a drain region 13b of n⁺-type. The source region 11b, the gate electrode 12b, and the drain region 13b each have a straight planar pattern extending parallel to each other. A part of the voltage blocking region 8 interposed between the source region 11b and the drain region 13b serves as a drift region 14b of the level shifter 10b. The GND potential is applied as a source potential (So potential) to the source region 11b. The drain potential (Dr potential) is applied to the drain region 13b.

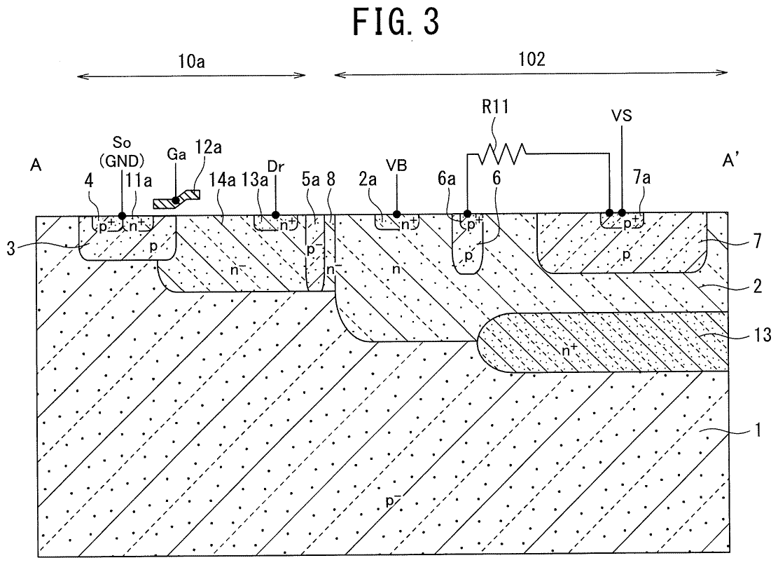

FIG. 3 is a cross-sectional view taken along line A-A′ passing through the level shifter 10a, the isolation region 5a, the slit region 6, the well region 7, and the like illustrated in FIG. 2. As illustrated in FIG. 3 in the region from the middle to the right side, the n-type well region 2 is provided at the upper part of the p⁻-type base body 1. The n⁺-type pickup region (the contact region) 2a having a higher impurity concentration than the well region 2 is provided at the upper part of the well region 2. The VB potential is applied to the contact region 2a.

The p-type well region 7 is provided at the upper part of the well region 2 separately from the contact region 2a. A pickup region (a contact region) 7a of p⁺-type having a higher impurity concentration than the well region 7 is provided at the upper part of the well region 7. The VS potential is applied to the contact region 7a. FIG. 2 omits the illustration of the contact region 7a illustrated in FIG. 3. The contact region 7a may have any planar pattern determined as appropriate.

The p-type slit region 6 is provided between the contact region 2a and the well region 7 at the upper part of the well region 2. The slit region 6 can be formed in the same step as the well region 7. The formation of the slit region 6 in the same step as the well region 7 can reduce the number of the manufacturing steps due to the elimination of the step of forming the slit region 6. The slit region 6 has substantially the same depth as the well region 7. The slit region 6 has substantially the same concentration as the well region 7 and has a higher impurity concentration than the base body 1.

The slit region 6 may be formed in a different step independently of the well region 7. The depth of the slit region 6, when formed independently of the well region 7, may be substantially the same as, greater than, or shallower than that of the well region 7. The impurity concentration of the slit region 6, when formed independently of the well region 7, may be substantially the same as, greater than, or less than that of the well region 7.

Increasing the depth of the slit region 6 can narrow the well region 2 that is a main noise current path, so as to improve the tolerance to noise. When a buried layer 13 is not provided under the slit region 6, the depth of the slit region 6 is set to a depth sufficient to prevent a depletion layer extending from the interface between the n-type well region 7 and the p-type base body 1 from reaching the bottom of the slit region 6, since the breakdown voltage is decreased if the depletion layer reaches the bottom of the slit region 6. When the buried layer 13 is provided under the slit region 6, the slit region 6 preferably has a depth as greater as possible since the depletion layer hardly extends toward the buried layer 13.

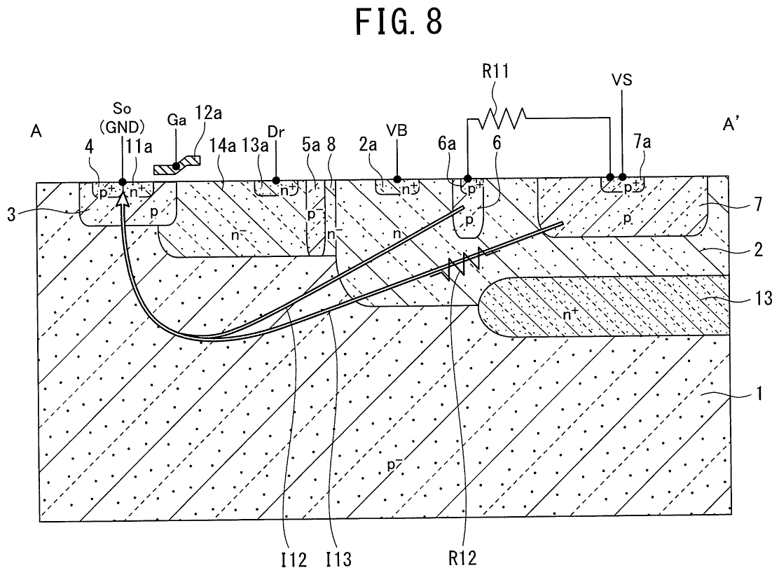

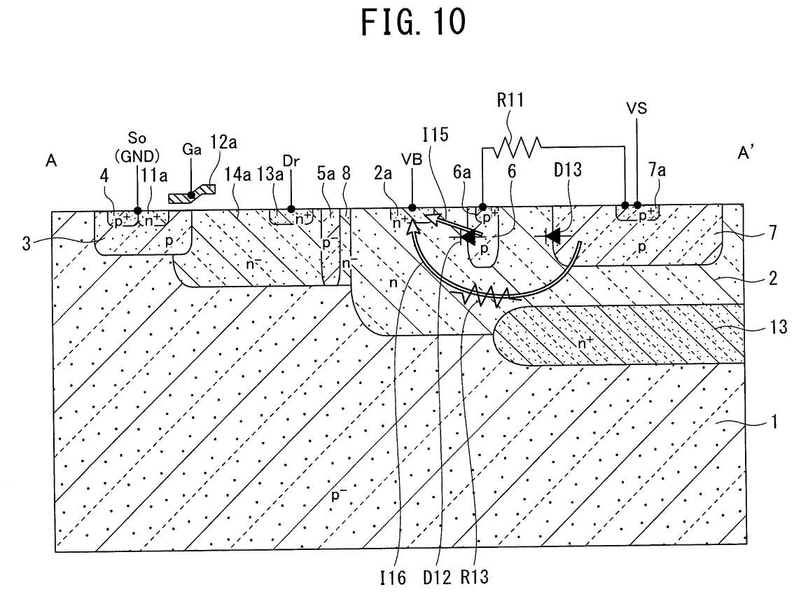

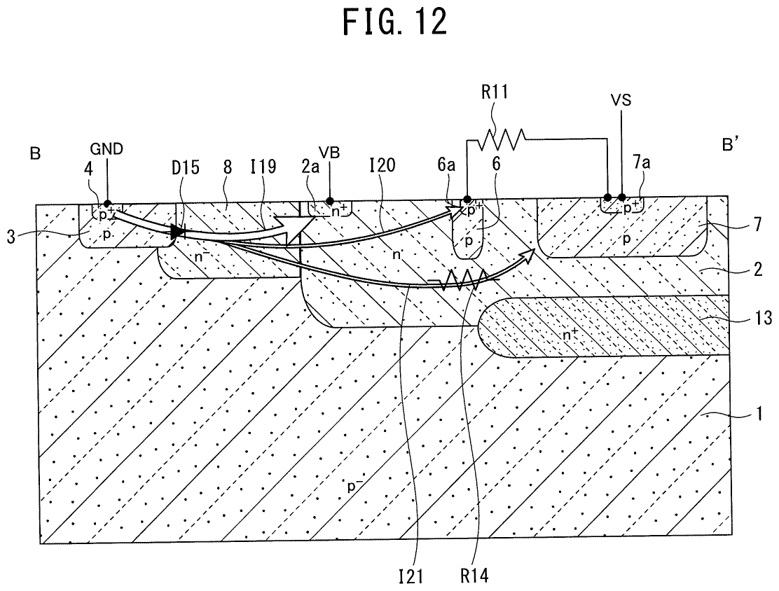

As described below, the slit region 6 can either serve as a noise-current source (refer to FIG. 8 and FIG. 10) or serve as a target to which noise current is absorbed (refer to FIG. 12). The case in which the slit region 6 serves as the noise-current source can improve the tolerance to noise such that the impurity concentration of the slit region 6 is decreased. The case in which the slit region 6 serves as a target to which noise current is absorbed can improve the tolerance to noise such that the impurity concentration of the slit region 6 is increased.

A pickup region (a contact region) 6a of p⁺-type having a higher impurity concentration than the slit region 6 is provided at the upper part of the slit region 6. The contact region 7a is connected to the contact region 6a via the resistor R11. The contact region 6a may be connected to the VS potential not via the contact region 7a but via the resistor R11. FIG. 2 omits the illustration of the contact region 6a illustrated in FIG. 3. The contact region 6a may have any planar pattern determined as appropriate. The resistor R11 is a polysilicon resistor, for example. The resistor R11 may be a diffusion resistor instead.

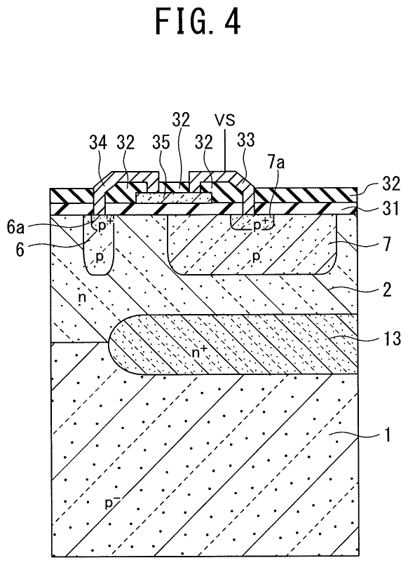

FIG. 4 is a cross-sectional view illustrating a region including a polysilicon resistor 35 when corresponding to the resistor R11 illustrated in FIG. 3. An insulating film 31 is provided on the respective top surfaces of the well region 2, the slit region 6, and the well region 7. The polysilicon resistor 35 is provided on the top surface of the insulating film 31. The polysilicon resistor 35 includes polysilicon heavily doped with p-type or n-type impurity ions. An insulating film 32 is provided so as to cover the top surface of the insulating film 31 and the respective top and side surfaces of the polysilicon resistor 35. The top surface of the insulating film 32 is provided with metal wiring layers 33 and 34. The metal wiring layer 33 connects the contact region 7a to one end of the polysilicon resistor 35 through openings (contact holes) provided in the respective insulating films 31 and 32. The metal wiring layer 34 connects the contact region 6a to the other end of the polysilicon resistor 35 through openings (contact holes) provided in the respective insulating films 31 and 32.

As illustrated in FIG. 3, the n⁺-type buried layer 13 having a higher impurity concentration than the well region 2 is provided in contact with the bottom surface of the well region 2. The buried layer 13 is provided uniformly in the horizontal direction to extend between the base body 1 and the well region 2. The buried layer 13 has a function of decreasing an amplification factor of a pnp bipolar transistor implemented by the p-type well region 7, the n-type well region 2, and the p-type base body 1, and further decreasing the amount of generated current. FIG. 3 illustrates the case in which the slit region 6 is provided at a position over the buried layer 13 to overlap with the edge of the buried layer 13 in the horizontal direction when viewed in the depth direction from the top surface side or the bottom surface side. Alternatively, the slit region 6 may be located on the inner side of the edge of the buried layer 13 (toward the well region 7) over the buried layer 13, or may be located at a position on the outer side of the edge of the buried layer 13 (toward the contact region 2a) without overlapping with the buried layer 13.

The provision of the slit region 6 at the position overlapping with or on the inner side of the edge of the buried layer 13 so as to be located over the buried layer 13 can further narrow the well region 2 that is a main noise current path due to the slit region 6 and the buried layer 13, so as to further improve the tolerance to noise, as compared with the case of not providing the buried layer 13 under the slit region 6.

The n-type voltage blocking region 8 is selectively provided along the outer circumference of the well region 2 so as to be in contact with each other at the upper part of the base body 1. The voltage blocking region 8 has a smaller depth than the well region 2. The p-type isolation region 5a is provided at the upper part of the base body 1 so as to penetrate the voltage blocking region 8 in the depth direction. The isolation region 5a has a greater depth than the voltage blocking region 8. The isolation region 5a has a higher impurity concentration than the base body 1.

The level shifter 10a is electrically isolated from the well region 2 by the isolation region 5a. A part of the voltage blocking region 8 surrounded by the isolation region 5a serves as the n-type drift region 14a of the level shifter 10a. The n⁺-type drain region 13a is provided at the upper part of the drift region 14a. The voltage blocking region 3 in contact with the drift region 14a serves as a p-type base region of the level shifter 10a. The n⁺-type source region 11a and the p⁺-type contact region 4 are provided at the upper part of the voltage blocking region 3. The gate electrode 12a is provided over the voltage blocking region 3 at a position interposed between the source region 11a and the drift region 14a with a gate insulating film (not illustrated) interposed. The cross-sectional structure of the level shifter 10b illustrated in FIG. 2 is common to that of the level shifter 10a illustrated in FIG. 3.

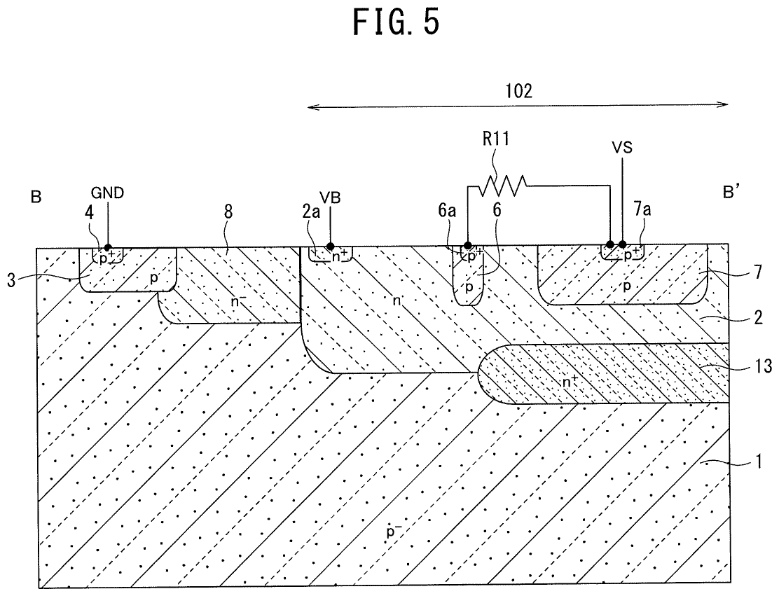

FIG. 5 is a cross-sectional view taken along line B-B′ perpendicular to line A-A′ shown in FIG. 2. The n-type well region 2 is provided at the upper part of the p⁻-type base body 1. The n⁺-type contact region 2a having a higher impurity concentration than the well region 2 is provided at the upper part of the well region 2. The VB potential is applied to the contact region 2a.

The p-type well region 7 is provided at the upper part of the well region 2 separately from the contact region 2a. The p⁺-type contact region 7a having a higher impurity concentration than the well region 7 is provided at the upper part of the well region 7. The VS potential is applied to the contact region 7a.

The p-type slit region 6 is provided between the contact region 2a and the well region 7 at the upper part of the well region 2. The p⁺-type contact region 6a having a higher impurity concentration than the slit region 6 is provided at the upper part of the slit region 6. The contact region 7a is connected to the contact region 6a via the resistor R11.

The n-type voltage blocking region 8 is selectively provided in contact with the well region 2 at the upper part of the base body 1. The p-type voltage blocking region 3 is provided in contact with the voltage blocking region 8 on the opposite side of the well region 2 at the upper part of the base body 1. The p⁺-type contact region 4 is provided at the upper part of the voltage blocking region 3. The GND potential is applied to the contact region 4. Expanding the depletion layer from the p-n junction between the voltage blocking region 8 and the voltage blocking region 3 mainly toward the voltage blocking region 8 can keep the breakdown voltage.

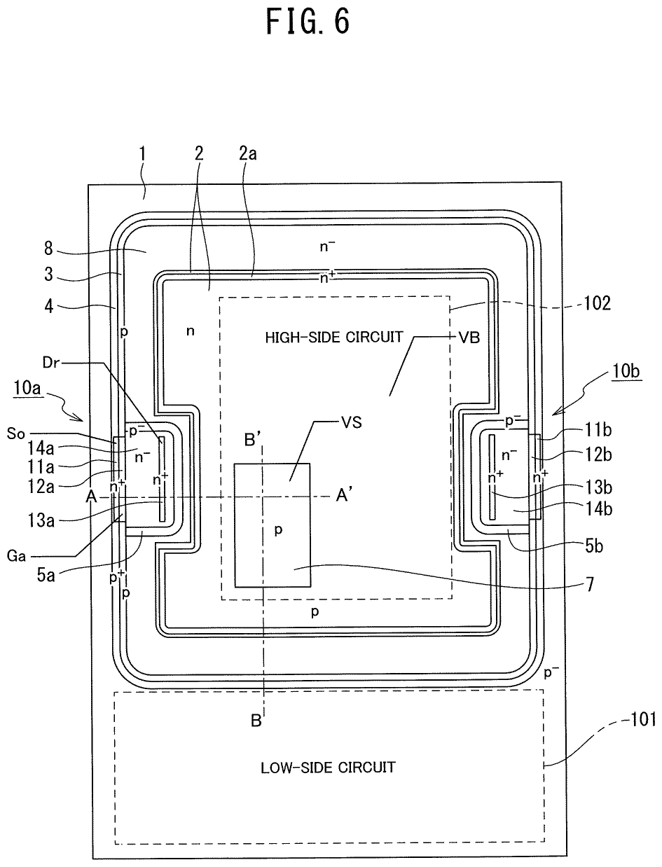

The operational effects of the semiconductor device according to the first embodiment are described below in comparison with a semiconductor device of a comparative example. FIG. 6 is a planar layout of the semiconductor device of the comparative example. As illustrated in FIG. 6, the semiconductor device of the comparative example differs from the semiconductor device according to the first embodiment illustrated in FIG. 2 in not including the p-type slit region 6 provided between the n⁺-type contact region 2a and the p-type well region 7, and in not including the resistor R11 connecting the slit region 6 and the well region 7 together.

The HVIC is operated in a state of keeping a potential relation in which the VB potential is greater than the VS potential, and the VS potential is greater than or equal to the GND potential (VB potential>VS potential>GND potential). However, a parasitic operation would be induced if this potential relation is broken because of noise or the like, which would cause wrong operations or damage. The following explanations are made with regard to the cases when falling into three different potential relations, a first potential relation in which the VS potential is greater than the VB potential, and the VB potential is much greater than the GND potential (VS potential>VB potential>>GND potential), a second potential relation in which the VB potential is smaller than the VS potential (VB potential<VS potential), and a third potential relation in which the VB potential is smaller than the GND potential (VB potential<GND potential).

### <Potential Relation of “VS Potential>VB Potential»>GND Potential”>

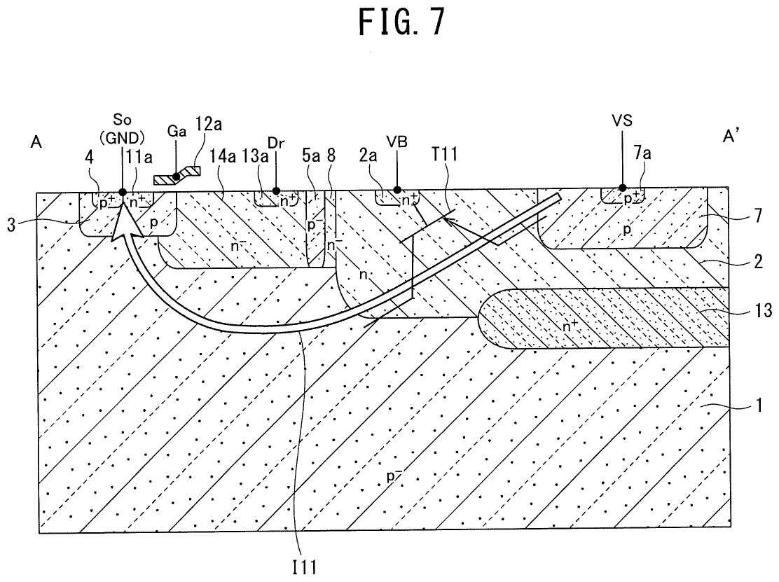

FIG. 7 is a cross-sectional view illustrating the semiconductor device of the comparative example taken along line A-A′ in FIG. 6, schematically indicating, by the arrow, a parasitic current I11 caused when falling into the potential relation of VS potential>VB potential>>GND potential. As illustrated in FIG. 7, when the semiconductor device of the comparative example falls into the potential relation of VS potential>VB potential>>GND potential due to a sharp rise of the VS potential because of noise, for example, a parasitic pnp bipolar transistor T11 formed by the p⁻-type base body 1, the n-type well region 2, and the p-type well region 7 operates with a high voltage applied, and thus causes the large parasitic current I11 to flow from the well region 7 toward the contact region 4 and the source region 11a, which would induce damage due to heat.

FIG. 8 is a cross-sectional view illustrating the semiconductor device according to the first embodiment taken along line A-A′ in FIG. 2, schematically indicating, by the arrows, parasitic currents I12 and I13 caused when falling into the potential relation of VS potential>VB potential>>GND potential. As illustrated in FIG. 8, when the semiconductor device according to the first embodiment falls into the potential relation of VS potential>VB potential>>GND potential, the parasitic currents I12 and I13 flow from the slit region 6 and the well region 7 connected to the VS potential toward the contact region 4 and the source region 11a. At this point, the flow of the parasitic current I12 from the slit region 6 is restricted by the connected resistor R11, and the flow of the parasitic current I13 from the well region 7 is restricted by the diffusion resistor R12 increased by the slit region 6, so as to suppress damage accordingly.

### <Potential Relation of “VB Potential<VS Potential”>

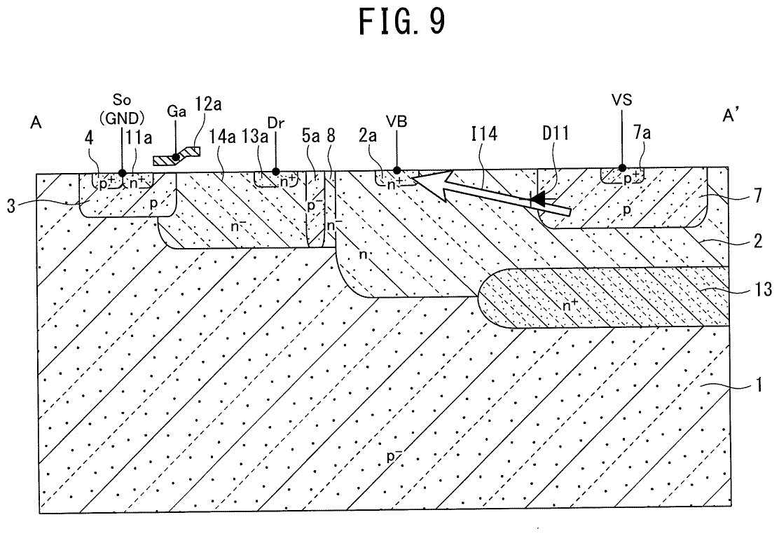

FIG. 9 is a cross-sectional view illustrating the semiconductor device of the comparative example taken along line A-A′ in FIG. 6, schematically indicating, by the arrow, a parasitic current I14 caused when falling into the potential relation of VB potential<VS potential. When the semiconductor device of the comparative example falls into the potential relation of VB potential<VS potential due to a sharp rise of the VS potential because of noise, for example, the parasitic current I14 that is a forward current with respect to a parasitic diode D11 formed by the p-type well region 7 and the n-type well region 2 flows toward the contact region 2a, as illustrated in FIG. 9. This causes carriers to be accumulated around the p-type isolation region 5a provided for the electrical isolation, which would lead to a deterioration of the isolating function to thus induce a wrong operation accordingly.

FIG. 10 is a cross-sectional view illustrating the semiconductor device according to the first embodiment taken along line A-A′ in FIG. 2, schematically indicating, by the arrows, parasitic currents I15 and I16 caused when falling into the potential relation of VB potential<VS potential. When the semiconductor device according to the first embodiment falls into the potential relation of VB potential<VS potential, the parasitic current I15 flows that is a forward current with respect to a parasitic diode D12 formed by the p-type slit region 6 and the n-type well region 2, and the parasitic current I16 flows that is a forward current with respect to a parasitic diode D13 formed by the p-type well region 7 and the n-type well region 2, as illustrated in FIG. 10. The respective parasitic currents I15 and I16 flow from the slit region 6 and the well region 7 connected to the VS potential toward the contact region 2a applied with the VB potential provided at the outermost circumference. At this point, the flow of the parasitic current I15 from the slit region 6 is restricted by the connected resistor R11, and the flow of the parasitic current I16 from the well region 7 is restricted by the diffusion resistor R13 increased by the slit region 6. This decreases the carriers accumulated around the contact region 2a applied with the VB potential provided at the outermost circumference, so as to suppress a wrong operation accordingly.

### <Potential Relation of “VB Potential<GND Potential”>

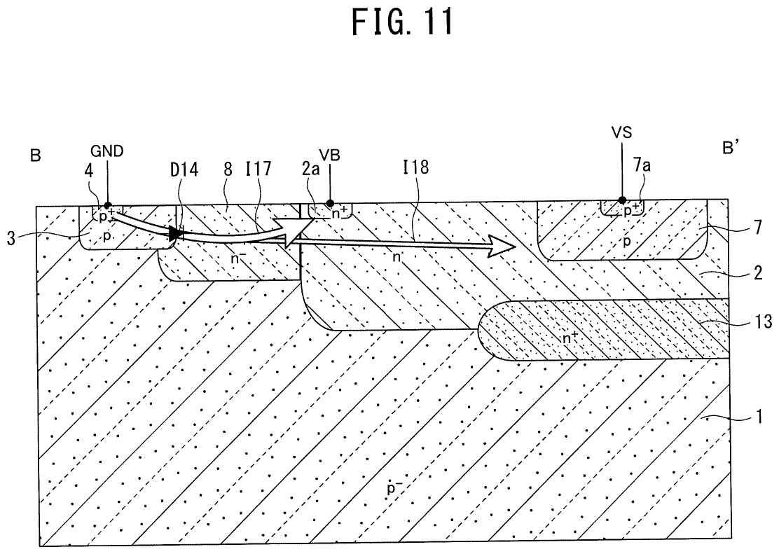

FIG. 11 is a cross-sectional view illustrating the semiconductor device of the comparative example taken along line B-B′ in FIG. 6, schematically indicating, by the arrows, parasitic currents I17 and I18 caused when falling into the potential relation of VB potential<GND potential. When the semiconductor device of the comparative example falls into the potential relation of VB potential<GND potential due to a decrease of the VB potential because of noise more than in a normal operation, for example, the parasitic currents I17 and I18 flow that are each a forward current with respect to a parasitic diode D14 formed by the p-type voltage blocking region 3 and the n⁻type voltage blocking region 8, as illustrated in FIG. 11. While the parasitic current I17 that is a part of the parasitic currents I17 and I18 flows toward the contact region 2a, the other parasitic current I18 reaches the high-side circuit 102, which would lead a logic circuit to cause a wrong operation.

FIG. 12 is a cross-sectional view illustrating the semiconductor device according to the first embodiment taken along line B-B′ in FIG. 2, schematically indicating, by the arrows, parasitic currents I19, I20, and I21 caused when falling into the potential relation of VB potential<GND potential. When the semiconductor device according to the first embodiment falls into the potential relation of VB potential<GND potential, the parasitic current I19 that is a part of the parasitic currents I19, I20, and I21 flowing from the contact region 4 applied with the GND potential further flows toward the contact region 2a, and the other parasitic current I20 flows toward the slit region 6, as illustrated in FIG. 12. Although the still other parasitic current I21 tends to further flow into the high-side circuit 102, most of the carriers are absorbed by the slit region 6 so that the entrance into the high-side circuit 102 is restricted, so as to suppress a wrong operation accordingly.

As described above, the semiconductor device according to the first embodiment, which has the configuration in which the p-type slit region 6 connected to the VS potential via the resistor R11 is provided between the well region 7 connected to the VS potential and the contact region 2a applied with the VB potential, can improve the tolerance to wrong operations or damage if falling into a potential relation different from a normal operation because of noise or the like, such as VS potential>VB potential»>GND potential, VB potential<VS potential, or VB potential<GND potential.

### Second Embodiment

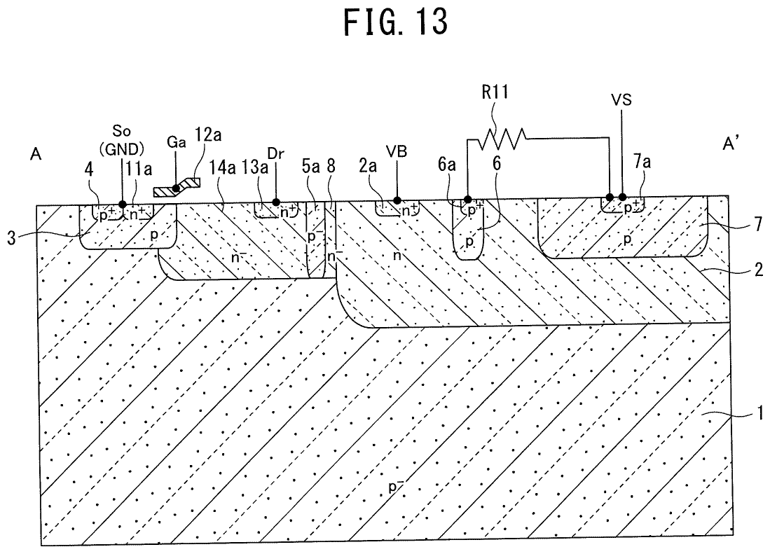

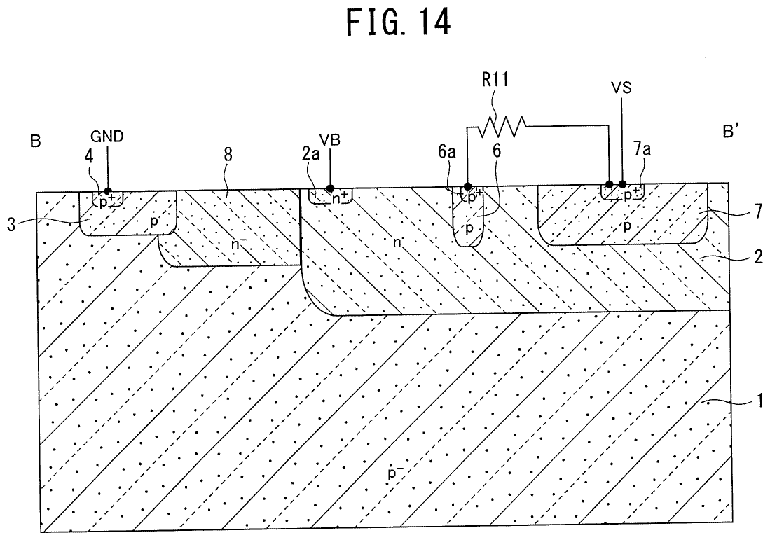

FIG. 13 is a cross-sectional view illustrating a semiconductor device according to a second embodiment, corresponding to the cross section of the semiconductor device according to the first embodiment illustrated in FIG. 3. FIG. 14 is a cross-sectional view illustrating the semiconductor device according to the second embodiment, corresponding to the cross section of the semiconductor device according to the first embodiment illustrated in FIG. 5.

As illustrated in FIG. 13 and FIG. 14, the semiconductor device according to the second embodiment differs from the semiconductor device according to the first embodiment illustrated in FIG. 3 and FIG. 5 in not including the n⁺-type buried layer 13 under the n-type well region 2. The bottom surface of the well region 2 is in contact with the p-type base body 1. The other configurations of the semiconductor device according to the second embodiment are substantially the same as those of the semiconductor device according to the first embodiment, and overlapping explanations are not repeated below.

The semiconductor device according to the second embodiment, which has the configuration in which the p-type slit region 6 connected to the VS potential via the resistor R11 is provided between the well region 7 connected to the VS potential and the contact region 2a applied with the VB potential, as in the case of the semiconductor device according to the first embodiment, can improve the tolerance to wrong operations or damage if falling into a potential relation different from a normal operation because of noise or the like, such as VS potential>VB potential>>GND potential, VB potential<VS potential, or VB potential<GND potential.

### Third Embodiment

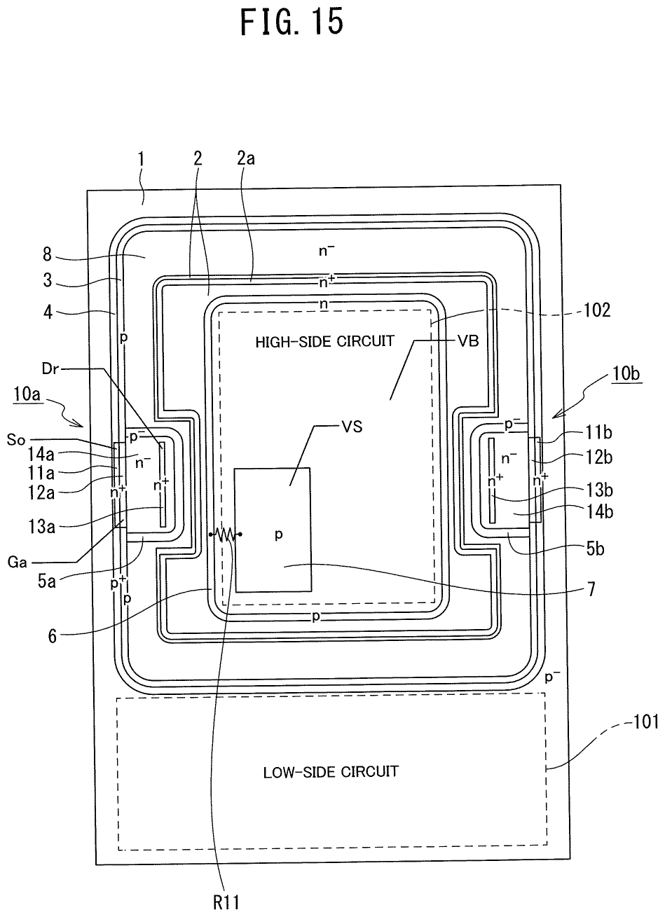

FIG. 15 is a cross-sectional view illustrating a semiconductor device according to a third embodiment. As illustrated in FIG. 15, the semiconductor device according to the third embodiment differs from the semiconductor device according to the first embodiment illustrated in FIG. 2 in that the p-type slit region 6 is provided into a loop-shaped state between the n⁺-type contact region 2a and the p-type well region 7. The slit region 6 is provided to surround the well region 7 and the high-side circuit 102. The other configurations of the semiconductor device according to the third embodiment are substantially the same as those of the semiconductor device according to the first embodiment, and overlapping explanations are not repeated below.

The semiconductor device according to the third embodiment, which has the configuration in which the p-type slit region 6 connected to the VS potential via the resistor R11 is provided between the well region 7 connected to the VS potential and the contact region 2a applied with the VB potential, as in the case of the semiconductor device according to the first embodiment, can improve the tolerance to wrong operations or damage if falling into a potential relation different from a normal operation because of noise or the like, such as VS potential>VB potential>>GND potential, VB potential<VS potential, or VB potential<GND potential. Further, the provision of the slit region 6 into the loop-shaped state can suppress wrong operations or damage much more reliably than the case of the partial provision of the slit region 6 if falling into a potential relation different from a normal operation.

### Fourth Embodiment

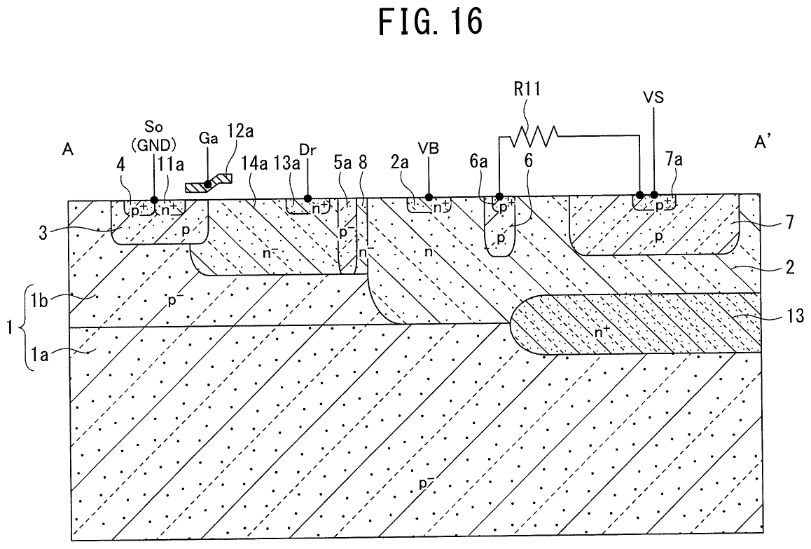

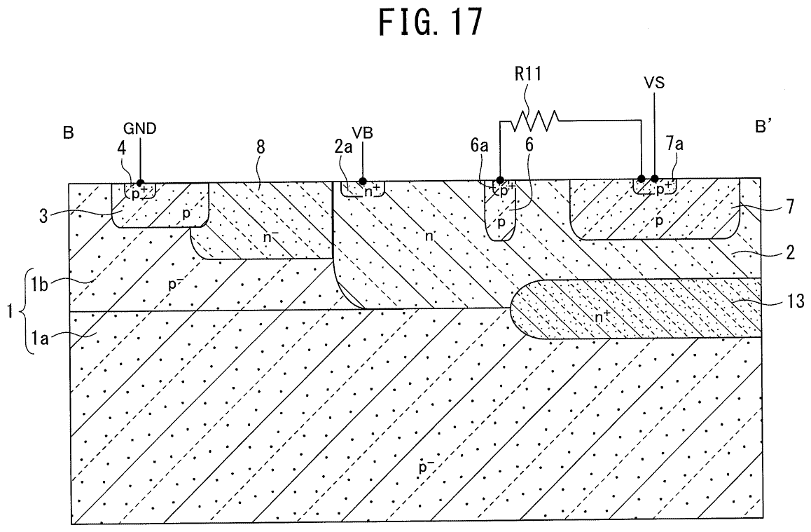

FIG. 16 is a cross-sectional view illustrating a semiconductor device according to a fourth embodiment, corresponding to the cross section of the semiconductor device according to the first embodiment illustrated in FIG. 3. FIG. 17 is a cross-sectional view illustrating the semiconductor device according to the fourth embodiment, corresponding to the cross section of the semiconductor device according to the first embodiment illustrated in FIG. 5.

As illustrated in FIG. 16 and FIG. 17, the semiconductor device according to the fourth embodiment differs from the semiconductor device according to the first embodiment illustrated in FIG. 3 and FIG. 5 in that the base body 1 is implemented by a p⁻-type semiconductor substrate 1a and a p⁻-type epitaxial layer 1b grown on the semiconductor substrate 1a. The other configurations of the semiconductor device according to the fourth embodiment are substantially the same as those of the semiconductor device according to the first embodiment, and overlapping explanations are not repeated below.

The semiconductor device according to the fourth embodiment, which has the configuration in which the p-type slit region 6 connected to the VS potential via the resistor R11 is provided between the well region 7 connected to the VS potential and the contact region 2a applied with the VB potential, as in the case of the semiconductor device according to the first embodiment, can improve the tolerance to wrong operations or damage if falling into a potential relation different from a normal operation because of noise or the like, such as VS potential>VB potential>>GND potential, VB potential<VS potential, or VB potential<GND potential.

### Fifth Embodiment

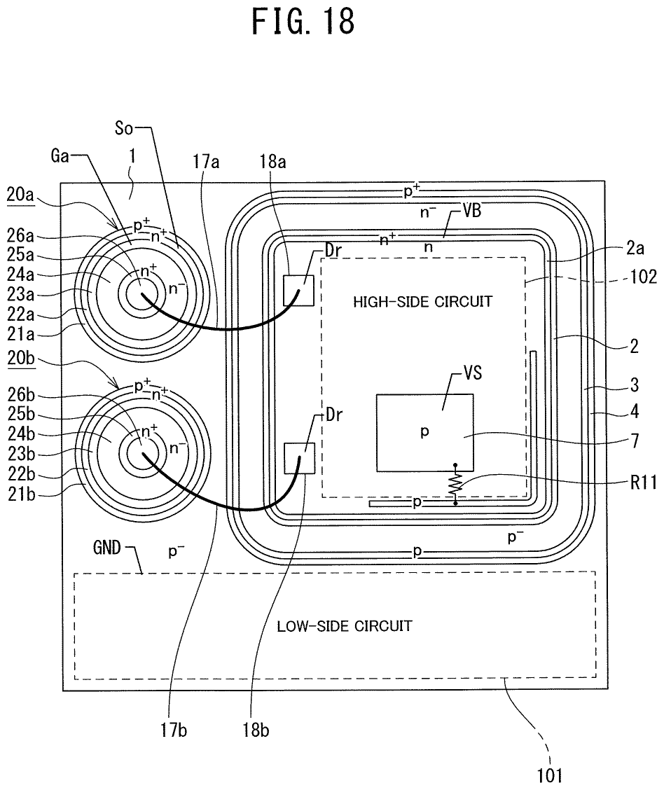

FIG. 18 is a plan view illustrating a semiconductor device according to a fifth embodiment. As illustrated in FIG. 18, the semiconductor device according to the fifth embodiment differs from the semiconductor device according to the first embodiment illustrated in FIG. 2 in including level shifters 20a and 20b formed by the WB method. The respective level shifters 20a and 20b are provided on the outer side of the p-type voltage blocking region 3. The level shifters 20a and 20b each have a substantially circular planar pattern. The level shifters 20a and 20b are each a high-voltage n-channel MOSFET.

The level shifter 20a includes a carrier supply region (a source region) 22a of n⁺-type, a gate electrode 23a, a drift region 24a of n-type, and a carrier reception region (a drain region) 25a of n⁺-type. The source region 22a has a circular planar pattern. The drift region 24a has a circular planar pattern provided on the inner circumferential side of the source region 22a. The gate electrode 23a is provided over a circular base region of p-type (not illustrated) interposed between the source region 22a and the drift region 24a with a gate insulating film (not illustrated) interposed. The drain region 25a has a circular planar pattern provided at the upper part of the drift region 24a.

A drain electrode 26a is provided at the upper part of the drain region 25a. The drain electrode 26a is connected to a pad 18a via a bonding wire 17a. A base region 21a of p⁺-type is provided on the outer circumferential side of the source region 22a. The base region 21a has a circular planar pattern.

The level shifter 20b has substantially the same structure as the level shifter 20a. The level shifter 20b includes a source region 22b of n⁺-type, a gate electrode 23b, a drift region 24b of n-type, and a drain region 25b of n⁺-type. The source region 22b has a circular planar pattern. The drift region 24b has a circular planar pattern provided on the inner circumferential side of the source region 22b. The gate electrode 23b is provided over a circular base region of p-type (not illustrated) interposed between the source region 22b and the drift region 24b with a gate insulating film (not illustrated) interposed. The drain region 25b has a circular planar pattern provided at the upper part of the drift region 24b.

A drain electrode 26b is provided at the upper part of the drain region 25b. The drain electrode 26b is connected to a pad 18b via a bonding wire 17b. A base region 21b of p⁺-type is provided on the outer circumferential side of the source region 22b. The base region 21b has a circular planar pattern. The other configurations of the semiconductor device according to the fifth embodiment are substantially the same as those of the semiconductor device according to the first embodiment, and overlapping explanations are not repeated below.

The semiconductor device according to the fifth embodiment, which has the configuration in which the p-type slit region 6 connected to the VS potential via the resistor R11 is provided between the well region 7 connected to the VS potential and the contact region 2a applied with the VB potential, as in the case of the semiconductor device according to the first embodiment, can improve the tolerance to wrong operations or damage if falling into a potential relation different from a normal operation because of noise or the like, such as VS potential>VB potential>>GND potential, or VB potential<GND potential. The semiconductor device according to the fifth embodiment does not need to consider a problem of wrong operations if falling into the potential relation of VB potential<VS potential in the case of the SS method, since the level shifters 20a and 20b are formed by the WB method.

### Other Embodiments

As described above, the invention has been described according to the first to fifth embodiments, but it should not be understood that the description and drawings implementing a portion of this disclosure limit the invention. Various alternative embodiments of the present invention, examples, and operational techniques will be apparent to those skilled in the art from this disclosure.

For example, while the respective semiconductor devices according to the first to fifth embodiments are illustrated above with the configuration including the high-side circuit 102 for one phase, the present invention is not limited to this case, and may be applied to a configuration including high-side circuits for three phases. Such a semiconductor device when provided with the high-side circuits for three phases may include, in each high-side circuit, a slit region of p-type connected to the VS potential via a resistor between a well region of p-type connected to a VS potential and a contact region of p⁺-type applied with a VB potential.

In addition, the respective configurations disclosed in the first to fifth embodiments can be combined together as appropriate without contradiction with each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
a base body of a first conductivity-type;
a first well region of a second conductivity-type provided in the base body so as to be provided with a high-side circuit;
a second well region of the first conductivity-type provided at an upper part of the first well region;
a first voltage blocking region of the second conductivity-type having a lower impurity concentration than the first well region and provided around the first well region;
a contact region of the second conductivity-type having a higher impurity concentration than the first well region and provided at an upper part of the first well region or the first voltage blocking region;
a slit region of the first conductivity-type provided between the second well region and the contact region at the upper part of the first well region and connected to the second well region via a resistor;
a second voltage blocking region of the first conductivity-type provided on an outer circumferential side of the first voltage blocking region so as to be in contact with each other; and
a level shifter provided to execute a signal transmission between a low-side circuit provided on an outer circumferential side of the second voltage blocking region and the high-side circuit.

2. The semiconductor device of claim 1, wherein the level shifter is provided in a part of each of the first voltage blocking region and the second voltage blocking region.

3. The semiconductor device of claim 2, further comprising an isolation region of the first conductivity-type provided to isolate the level shifter and the first well region from each other.

4. The semiconductor device of claim 2, wherein the slit region is provided between the level shifter and the second well region.

5. The semiconductor device of claim 2, wherein
a carrier reception region of the level shifter is provided at an upper part of the first voltage blocking region, and
a carrier supply region of the level shifter is provided at an upper part of the second voltage blocking region.

6. The semiconductor device of claim 1, wherein the level shifter is provided on the outer circumferential side of the second voltage blocking region.

7. The semiconductor device of claim 1, further comprising a buried layer of the second conductivity-type having a higher impurity concentration than the first well region and provided under the first well region.

8. The semiconductor device of claim 7, wherein the slit region is provided at a position overlapping with an edge of the buried layer.

9. The semiconductor device of claim 1, wherein the slit region is provided selectively between the second well region and the contact region.

10. The semiconductor device of claim 1, wherein the slit region is provided into a loop-shaped state to surround the second well region and the high-side circuit.

11. The semiconductor device of claim 1, wherein the slit region has a depth common to that of the second well region.

12. The semiconductor device of claim 1, wherein the slit region has an impurity concentration common to that of the second well region.

13. The semiconductor device of claim 1, wherein the resistor is a polysilicon resistor.

14. The semiconductor device of claim 1, wherein
a first potential is applied to the contact region,
a second potential lower than the first potential is applied to the second well region, and
the second potential is applied to the slit region via the resistor.
